(19) United States
(12) Patent Application Publication
(10) Pub. No.: US 2025/0347000 A1
(43) Pub. Date: Nov. 13, 2025

(54) DISC SUPPORT FOR FLUID DISTRIBUTION

(71) Applicant: Western Digital Technologies, Inc., San Jose, CA (US)

(72) Inventors: Anand Sethuraman, Fremont, CA (US); David Lenguyen, San Jose, CA (US); George Leece, Salinas, CA (US); Ragu Govindaraju, Fremont, CA (US)

(21) Appl. No.: 18/657,590

(22) Filed: May 7, 2024

(51) Int. Cl. C23C 16/458; C23C 14/50; G11B 23/00

(52) U.S. Cl. CPC C23C 16/4583; C23C 14/50; G11B 23/00

(57) ABSTRACT

Disclosed herein is an apparatus for supporting discs. The apparatus includes an elongated member. The elongated member includes an exterior surface having grooves spaced apart from each other along a length of the elongated member. Each one of the grooves is configured to receive a portion of a corresponding one of the discs. The elongated member includes an interior channel extending along the length of the elongated member. The elongated member includes fluid release portions spaced apart from each other along the length of the elongated member and each having at least one opening extending from the interior channel to the exterior surface. Each one of the grooves is interposed between corresponding adjacent ones of the fluid release portions.

### FIELD

This disclosure relates generally to disc supports, and more particularly to disc supports for fluid distribution.

### BACKGROUND

Magnetic storage devices, such as hard disc drives (“HDDs”), are widely used to store digital data or electronic information for enterprise data processing systems, computer workstations, portable computing devices, digital audio players, digital video players, and the like.

HDDs include magnetic discs coated with magnetic recording material to store and retrieve digital data. During the manufacturing process, these discs undergo various treatments with different fluids to prepare them for performance as part of the HDD. Supports, or “mandrels”, can hold these discs in place during the fluid distribution process, but the application of treatments and fluids while held in place can be difficult.

### SUMMARY

The subject matter of the present application has been developed in response to the present state of manufacturing processes for making magnetic storage devices, and in particular, in response to the shortcomings of such manufacturing processes that have not yet been fully solved by currently available magnetic storage devices. Accordingly, the examples of the present disclosure overcome at least some of the shortcomings of the prior art.

Disclosed herein is an apparatus for supporting discs. The apparatus includes an elongated member. The elongated member includes an exterior surface having grooves spaced apart from each other along a length of the elongated member. Each one of the grooves is configured to receive a portion of a corresponding one of the discs. The elongated member includes an interior channel extending along the length of the elongated member. The elongated member includes fluid release portions spaced apart from each other along the length of the elongated member and each having at least one opening extending from the interior channel to the exterior surface. Each one of the grooves is interposed between corresponding adjacent ones of the fluid release portions. The preceding subject matter of this paragraph characterizes example 1 of the present disclosure.

Each one of the grooves defines a fluid non-releasing portion of the exterior surface. The preceding subject matter of this paragraph characterizes example 2 of the present disclosure, wherein example 2 also includes the subject matter according to example 1, above.

The elongated member further includes a fluid port at a proximal end of the elongated member. The interior channel is fluidically open to the fluid port. The interior channel is fluidically closed at a distal end of the elongated member. The fluid is flowable into the interior channel, from the fluid port, and out of the interior channel, through the at least one opening of each one of the fluid release portions. The preceding subject matter of this paragraph characterizes example 3 of the present disclosure, wherein example 3 also includes the subject matter according to example 2, above.

The fluid is flowable through the interior channel in a longitudinal direction and through the at least one opening of each one of the fluid release portions is in a radial direction perpendicular to longitudinal direction. The preceding subject matter of this paragraph characterizes example 4 of the present disclosure, wherein example 4 also includes the subject matter according to any of examples 1-3, above.

At least one of the fluid release portions is closer to a proximal end of the elongated member than to a distal end of the elongated member. At least one of the fluid release portions is closer to the distal end than to the proximal end. At least one of the fluid release portions closer to the proximal end is less porous than the at least one of the fluid release portions close to the distal end. The preceding subject matter of this paragraph characterizes example 5 of the present disclosure, wherein example 5 also includes the subject matter according to any of examples 1-4, above.

Each one of the at least one of the fluid release portions closer to proximal end includes a first number of openings. Each one of the at least one of the fluid release portions closer to the distal end includes a second number of openings. The second number is greater than the first number. The preceding subject matter of this paragraph characterizes example 6 of the present disclosure, wherein example 6also includes the subject matter according to any of examples 1-5, above.

The elongated member includes a mandrel and a portion of each one of the discs received by each one of the grooves includes a portion of a central opening of each one of the discs. The preceding subject matter of this paragraph characterizes example 7 of the present disclosure, wherein example 7 also includes the subject matter according to any of examples 1-6, above.

Each one of the fluid release portions extends about an entire circumference of the elongated member. The preceding subject matter of this paragraph characterizes example 8 of the present disclosure, wherein example 8 also includes the subject matter according to any of examples 1-7, above.

The grooves extend about less than the entire circumference of the elongated member. The preceding subject matter of this paragraph characterizes example 9 of the present disclosure, wherein example 9 also includes the subject matter according to any of examples 1-8 above.

The at least one opening of each one of the fluid release portions has a maximum width and a ratio of the maximum width to a thickness of the corresponding disc is between, and inclusive of, 0.0002 and 0.20. The preceding subject matter of this paragraph characterizes example 10 of the present disclosure, wherein example 10 also includes the subject matter according to any one of examples 1-10, above.

The fluid release portions have a porosity of between, and inclusive of, 6 percent and 60 percent. The preceding subject matter of this paragraph characterizes example 11 of the present disclosure, wherein example 11 also includes the subject matter according to any one of examples 1-10, above.

Each groove of the grooves is configured to receive the portion of the corresponding one of the discs such that an elongated-member central axis of the elongated member is parallel to and offset from a disc central axis of the corresponding disc. The preceding subject matter of this paragraph characterizes example 12 of the present disclosure, wherein example 12 also includes the subject matter according to any one of examples 1-11, above.

The grooves and the fluid release portions are made of a metallic material. The preceding subject matter of this paragraph characterizes example 13 of the present disclosure, wherein example 13 also includes the subject matter according to any one of examples 1-12, above.

Also disclosed herein is a system for supporting discs. The system includes an apparatus, which includes an elongated member. The elongated member includes an exterior surface having grooves spaced apart from each other along a length of the elongated member. Each one of the grooves is configured to receive a portion of a corresponding one of the discs. The elongated member includes an interior channel extending along the length of the elongated member. The elongated member includes fluid release portions spaced apart from each other along the length of the elongated member and each having at least one opening extending from the interior channel to the exterior surface. Each one of the grooves is interposed between corresponding adjacent ones of the fluid release portions. The apparatus includes a fluid port at a proximal end of the elongated member. The interior channel is fluidically open to the fluid port. The system includes a fluid source fluidically open to the fluid port. The preceding subject matter of this paragraph characterizes example 14 of the present disclosure.

The system includes an enclosed chamber defining an interior cavity. The elongated member is within the interior cavity and fixedly coupled to a surface of the enclosed chamber at the fluid port. The elongated member extends substantially perpendicular to the surface. The preceding subject matter of this paragraph characterizes example 15 of the present disclosure, wherein example 15 also includes the subject matter according to example 14, above.

Additionally disclosed herein is a method. The method includes loading each one of a plurality of discs into a corresponding one of a plurality of grooves formed in an exterior surface of an elongated member so that the plurality of discs are perpendicular relative to a central axis of the elongated member. The method includes flowing fluid into an interior channel of the elongated member that is parallel to the central axis. The method includes flowing the fluid from the interior channel, through fluid release portions of the elongated member, and into contact with the plurality of discs. Each one of the fluid release portions is adjacent a corresponding one of the plurality of grooves or interposed between corresponding adjacent ones of the plurality of grooves. The preceding subject matter of this paragraph characterizes example 16 of the present disclosure.

Fluid from at least one of the fluid release portions contacts only one side of one disc of the plurality of discs and fluid from at least one other fluid release portion of the fluid release portions contacts at least one side of at least two discs of the plurality of discs. The preceding subject matter of this paragraph characterizes example 17 of the present disclosure, wherein example 17 also includes the subject matter according to example 16, above.

Flowing the fluid into the interior channel port includes flowing the fluid through the interior channel in a longitudinal direction. In some examples, flowing the through the fluid release portions includes flowing the fluid in a radial direction that is perpendicular to the longitudinal direction. The preceding subject matter of this paragraph characterizes example 18 of the present disclosure, wherein example 18 also includes the subject matter according to any one of examples 16 or 17, above.

Each fluid release portion includes at least one opening, and flowing the fluid through the fluid release portions includes flowing the fluid through the at least one opening. The subject matter of this paragraph characterizes example 19 of the present disclosure, wherein example 19 also includes the subject matter according to any of examples 16-18, above.

The portion of the corresponding one of the discs includes only part of an opening of the disc that is less than an entire circumference of the opening. Loading each one of the plurality of discs into a corresponding one of the grooves of the elongated member includes inserting the elongated member through the opening. The subject matter of this paragraph characterizes example 20 of the present disclosure, wherein example 20 also includes the subject matter according to any of examples 16-19, above.

The described features, structures, advantages, and/or characteristics of the subject matter of the present may be combined in any suitable manner in one or more examples and/or implementations. In the following description, numerous specific details are provided to impart a thorough understanding of examples of the subject matter of the present disclosure. One skilled in the relevant art will recognize that the subject matter of the present disclosure may be practiced without one or more of the specific features, details, components, materials, and/or methods of a particular example or implementation. In other instances, additional features and advantages may be recognized in certain examples and/or implementations that may not be present in all examples or implementations. Further, in some instances, well-known structures, materials, or operations are not shown or described in detail to avoid obscuring aspects of the subject matter of the present disclosure. The features and advantages of the subject matter of the present disclosure will become more fully apparent from the following description and appended claims, or may be learned by the practice of the subject matter as set forth hereinafter.

### BRIEF DESCRIPTION OF THE DRAWINGS

In order that the advantages of the disclosure will be readily understood, a more particular description of the disclosure briefly described above will be rendered by reference to specific examples that are illustrated in the appended drawings. Understanding that these drawings depict only typical examples of the disclosure and are not therefore to be considered to be limiting of its scope, the subject matter of the present application will be described and explained with additional specificity and detail through the use of the accompanying drawings, in which:

FIG. 1 is a perspective view of system for fluid distribution onto discs, according to one or more examples of the present disclosure;

FIG. 2 is a side elevation view of the system of FIG. 1, according to one or more examples of the present disclosure;

FIG. 3A is a perspective view of an apparatus for supporting discs, according to one or more examples of the present disclosure;

FIG. 3B is a cross-sectional side elevation view of the apparatus of FIG. 3A, taken along the line 3 of FIG. 3A, according to one or more examples of the present disclosure;

FIG. 4A is a cross-sectional side elevation view of the apparatus of FIG. 3A, taken along the line 3 of FIG. 3A and shown with discs loaded onto the apparatus, according to one or more examples of the present disclosure;

FIG. 4B is a close-up cross-sectional side elevation view of the apparatus of FIG. 3A, taken along the line 3 of FIG. 3A of FIG. 3A and shown with discs loaded onto the apparatus, according to one or more examples of the present disclosure;

FIG. 4C is a front elevation view of an apparatus for supporting discs with discs loaded onto the apparatus, according to one or more examples of the present disclosure; and

FIG. 5 is a schematic flow chart of a method of distributing fluid onto one or more discs, according to one or more examples of the present disclosure.

### DETAILED DESCRIPTION

Reference throughout this specification to “one example,” “an example,” or similar language means that a particular feature, structure, or characteristic described in connection with the example is included in at least one example of the present disclosure. Appearances of the phrases “in one example,” “in an example,” and similar language throughout this specification may, but do not necessarily, all refer to the same example. Similarly, the use of the term “implementation” means an implementation having a particular feature, structure, or characteristic described in connection with one or more examples of the present disclosure, however, absent an express correlation to indicate otherwise, an implementation may be associated with one or more examples.

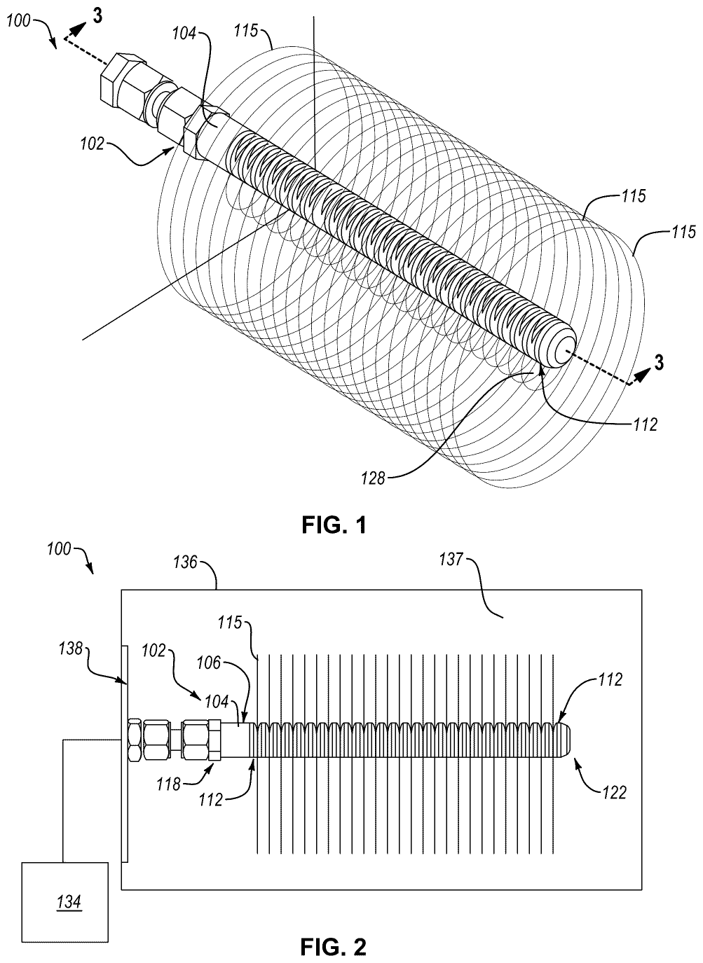

Various electronic and non-electronic devices include discs. For example, magnetic storage devices include magnetic storage discs, such as discs 115 shown in FIG. 1. Disclosed herein is a manufacturing process, and corresponding apparatus 102 and a system 100, for making discs, such as the discs 115, which involves distributing a fluid onto at least one surface of each of the discs. Examples of the present disclosure can help to distribute such fluids onto the discs more uniformly by routing the fluid through a mandrel being used to support those discs.

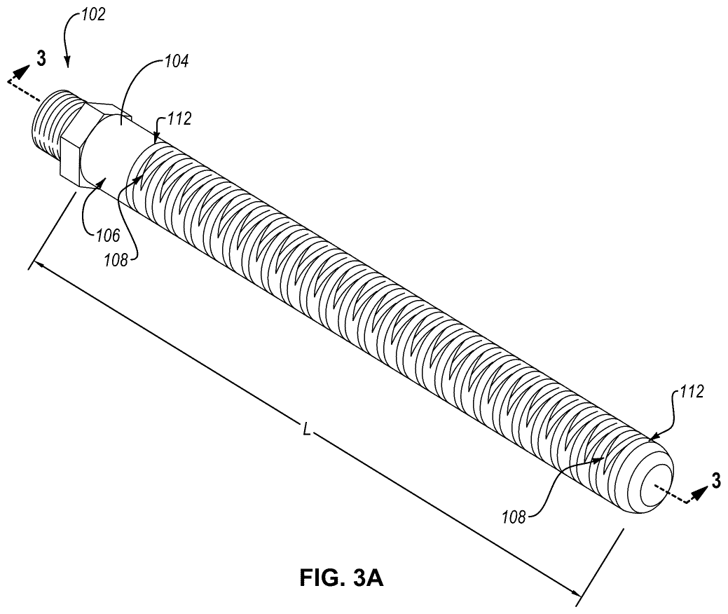

As shown in FIGS. 1 and 2, examples of the present disclosure include a system 100 for fluid distribution onto the discs 115. In some examples, the system 100 includes an apparatus 102 for supporting the discs 115 as fluids are distributed onto the discs 115. In some examples, the apparatus 102 supports the discs 115 during various stages of a magnetic storage device manufacturing process, or a process for readying the discs 115 for use in a magnetic storage device. According to examples of the present disclosure, the apparatus 102 also serves to help route fluids onto the discs 115.

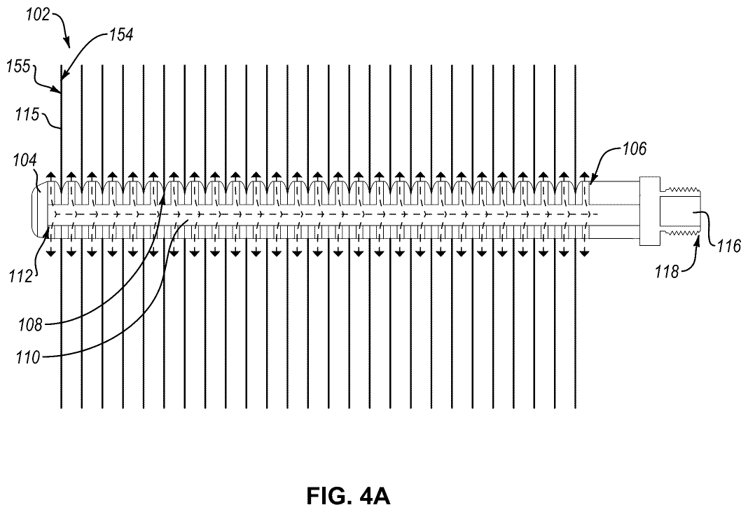

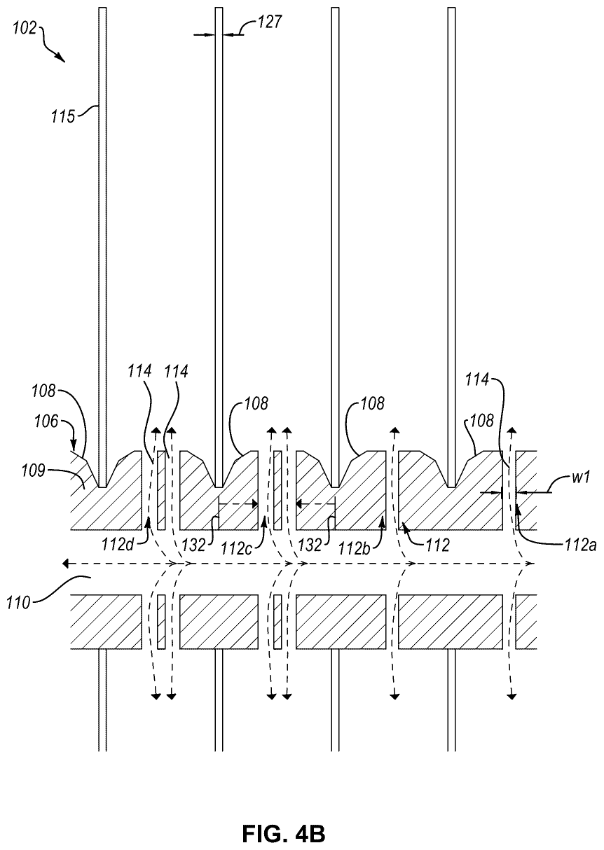

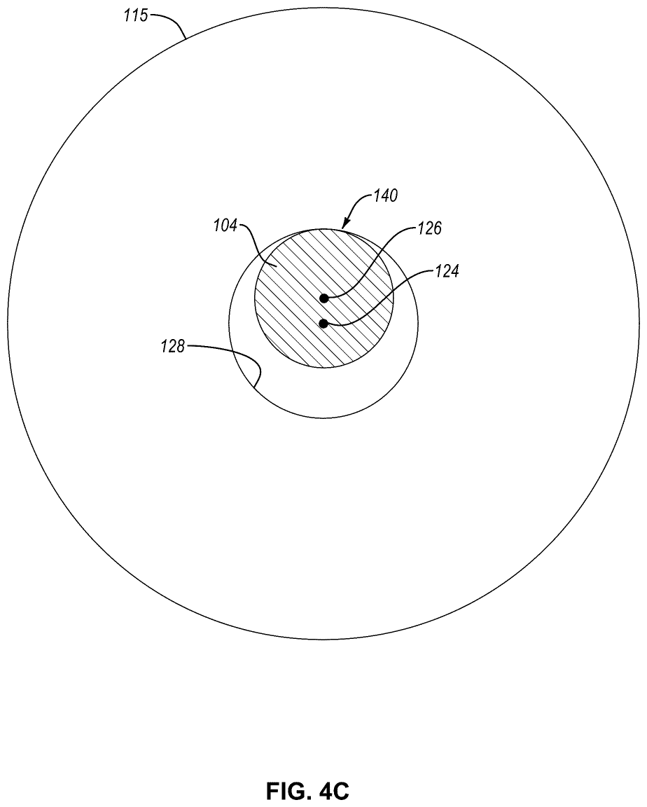

In some examples, the apparatus 102 is configured to receive the discs 115. The apparatus 102 includes a mandrel configured to pass through openings 128 in the discs 115 and support the discs 115 by engaging the openings 128. As shown in FIG. 4A, in some examples, the apparatus 102 includes an elongated member 104 that is configured to receive and release fluid, such that the fluid flows through an interior channel 110 of the elongated member 104, radially out of the elongated member 104 via fluid release portions 112 of the elongated member 104, and onto the discs 115 supported by the elongated member 104.

In some examples, the discs 115 are discs of a magnetic storage device. In some examples, a magnetic storage device includes a hard disc drive (HDD). However, in other examples, the magnetic storage device can be any of various magnetic storage devices without departing from the essence of the subject matter of the present disclosure. In some examples, elements of the magnetic storage device are configured to detect magnetic properties (e.g., magnetic bit patterns) of a disc and convert the magnetic properties into an electrical signal. In some examples, elements of the magnetic storage device are configured to change the magnetic properties of the discs responsive to an electrical signal.

Each one of the discs 115 may be any of various types of magnetic recording media. Generally, in one example, each disc 115 includes a substrate and a magnetic material applied directly or indirectly onto the substrate. In some examples, the “fluid” includes the magnetic material, and the magnetic material is applied onto the substrate through the fluid-releasing portions 112, as shown in FIG. 4A. For example, the magnetic material of the discs 115 may be conventional granular magnetic recording discs or wafers that have magnetic layer bits with multiple magnetic grains on each bit. In granular magnetic media, all of the bits are co-planar and opposing data storage surfaces 154, 155 of the discs 115 are substantially smooth and continuous. In one example, each bit has a magnetic dipole moment that can either have an in-plane (longitudinal) orientation or an out-of-plane (perpendicular) orientation.

In some examples, the disc 115 includes a substrate, and the fluid is deposited onto the substrate. The fluid in such examples can include a gas, a liquid, a vapor, a plasma, particles of a solid material, and/or any combination thereof. In some examples, the fluid includes perfluorinated lubricant in a vapor state. In yet certain examples, the fluid includes particles of solid material, such as particles of a metal alloy. The particles of the metal alloy can be distributed onto the discs 115 to form a thin, magnetic film on each disc 115. Moreover, in certain examples, the particles are deposited onto the discs 115 via a vacuum deposition process, such as magnetron sputtering, and/or a chemical vapor deposition process. In some examples, the fluid includes an inert gas, such as argon, nitrogen, and/or any combination thereof. The fluid can include a gas configured to help remove contaminants and/or residual materials from the discs 115, including, but not limited to, oxygen, argon, and/or any combination thereof. According to certain examples, the fluid includes a gas formulated to etch the disc 115 surfaces, including, but not limited to, fluorine, chlorine, and/or any combination thereof. In some examples, the fluid includes other gases, such as hydrogen, nitrogen, helium, silane, nitrogen trifluoride, and/or any combination thereof.

In alternative examples, the fluid includes a liquid, which can be formulated to remove material from the discs 115. The liquid includes high-purity deionized water in some examples. In one particular example, the liquid includes perfluorinated polyethers.

In yet other examples, the fluid includes a vapor, which can include protective and/or anti-corrosive material, such as amorphous carbon. In some examples, the vapor includes at least one of iron, nickel, cobalt, magnetic alloys, and/or any combination thereof.

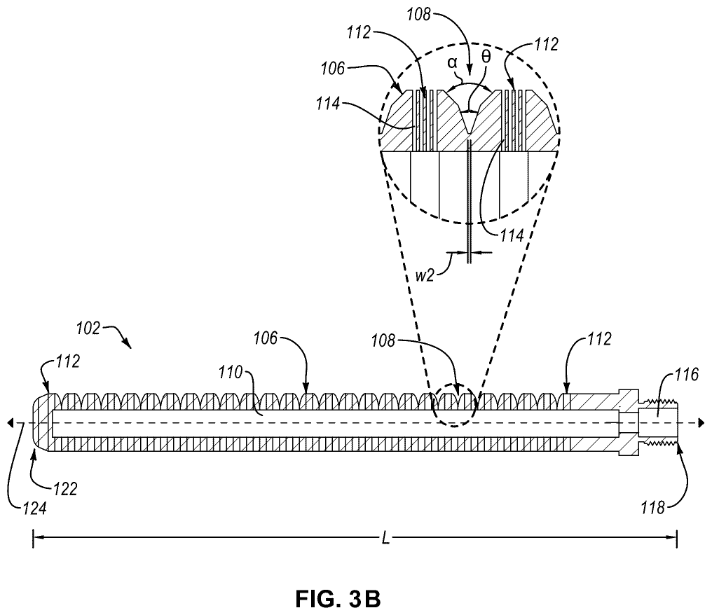

Referring to FIGS. 3A and 3B, in some examples, the elongated member 104 of the apparatus 102 includes an exterior surface 106 having porous (e.g., fluid-releasing portions 112) and non-porous portions (e.g., grooves 108). The grooves 108 are spaced apart from each other along a length L of the elongated member 104, which is parallel to a central axis 124 of the elongated member 104. In some examples, the grooves 108 are spaced uniformly apart from each other. Referring to FIG. 4B, in one particular example, the ratio of a thickness 127 of each one of the discs 115 to the spacing between adjacent ones of the grooves 108 is approximately 0.1. In some examples, the ratio of the thickness 127 of each one of the discs 115 to the spacing between adjacent ones of the grooves 108 is between, and inclusive of, 0.05 and 0.15.

Referring to FIG. 3A, in some examples, the grooves 108 extend only partially around an outer perimeter (e.g., outer circumference) of the elongated member 104. As such, in some examples, the grooves 108 receive only a portion 140 of an opening 128 of the discs 115, and a center line 124 of the discs 115 is offset from a center line 126 of elongated member 104, when the discs are supported on the elongated member 104 within the grooves 108, as shown in FIG. 4C. In some examples, each groove 108 is shaped to form a friction fit with the portion 140 of the opening 128. In some examples, the elongated member 104 is oriented (e.g., horizontal relative to ground) such that gravity can help keep the discs 115 in place within the grooves 108, as shown in FIG. 1. Referring to FIG. 3B, in some examples, the grooves 108 are defined by opposing angled or chamfered surfaces formed in the exterior surface 106. The angled or chamfered surfaces of the grooves 108 are angled at various angles relative to each other. For example, as shown in the detailed view of FIG. 3B, the angled surfaces of the groove 108 can define at least a first angle a between the angled surfaces. Additionally, in certain examples, the angled surfaces of the grooves 108 are configured to define the first angle α between corresponding radially outward portions of the surfaces and a second angle Θ between corresponding radially inward portions of the surfaces. The second angle Θ is less than the first angle α. In some examples, the second angle Θ is less than 90 degrees, such as approximately 40 degrees. In some examples, the second angle Θ is not less than 30 degrees and not greater than 50 degrees. In one example, the first angle α is approximately 90 degrees. In yet certain examples, the first angle α is between, and inclusive of, 80 and 100 degrees. In some examples, the disc 115 is configured to fit within the second angle Θ. The larger first angle α helps to locate and facilitate an initial reception of a disc 115 (e.g., approximately locate the disc 115 in the groove 108), and the smaller second angle Θ receives and secures the disc 115 (e.g., precisely locate the disc 115 in the groove 108).

In some examples, one or more of the first angle α, the second angle Θ, a depth 144 of the groove 108, and/or a minimum width 146 of the groove 108 are dependent on a thickness 127 of the discs 115. In some examples, the thickness 127 of the discs is less than 0.7 millimeters (mm), such as approximately 0.635 mm. In some examples, the depth 144 of the groove 108 is approximately 2 mm. In some examples, a ratio of the thickness 127 of the disc 115 to the depth 144 of the groove is approximately 0.3. In some examples, the minimum width w2 of the groove 108, or a width at the deepest portion of the groove 108, is approximately 0.2 mm. In some examples, a ratio of the minimum width w2 to the thickness 127 of the disc 115 is between, and inclusive of, 0.15 and 0.4.

In some examples, each one of the grooves 108 defines a fluid non-releasing portion 109 of the exterior surface 106. In some examples, the grooves 108 are defined by a non-porous material, or a material that configured not to release fluid from within the elongated member 104. In some examples, the grooves 108 do not include any openings in the elongated member 104.

The elongated member 104 also includes fluid release portions 112. The fluid release portions 112 are spaced apart from each other along the length L of the elongated member 104. In some examples, the spacing between adjacent ones of the fluid release portions 112 is substantially equal to the spacing between adjacent ones of the grooves 108. In some examples, the spacing between the fluid release portions 112 is substantially uniform. In some examples, each one of the fluid release portions 112 is positioned adjacent to at least one groove 108. Endmost ones of the fluid release portions 112 are adjacent to only a corresponding one of the grooves 108 (e.g., endmost grooves). Each one of the other grooves 108 is adjacent and between two adjacent grooves 108. Accordingly, in some examples, each groove 108 is interposed between two corresponding adjacent fluid release portions 112. In some examples, the elongated member includes a quantity of grooves 108 (e.g., at least twenty-five grooves), each configured to receive a portion of a corresponding one of the discs 115. In some examples, the quantity of fluid releasing portions 112 is one greater than the quantity of grooves 108. Accordingly, in some examples, the elongated member 104 includes at least twenty-six fluid releasing portions 112.

Referring to FIGS. 3B and 4B, in some examples, each one of the fluid release portions 112 includes at least one opening 114 extending from the interior channel 110 to the exterior surface 106. In some examples, the fluid is flowable through the interior channel 110 in a longitudinal direction and through the openings 114 in a radial direction perpendicular to the longitudinal direction. In some examples, the radial direction is substantially parallel to a data storage surface 154, 155 of the discs 115 when properly supported on the elongated arm 104 within the grooves 108. In some examples, the fluid contacts one or both of the surfaces 154, 155 of one or two adjacent discs as it flows in the radial direction out of the openings 114 and along one disc or between adjacent discs.

In some examples, the fluid release portions 112 have a porosity between, and inclusive of, 6 and 60 percent. In some examples, the fluid release portions 112 have a porosity between, and inclusive of, 20 and 50 percent. In some examples, the non-fluid releasing portions defined by the grooves 108 have a porosity less than that the porosity of the fluid release portions 112. In some examples, the porosity of the non-fluid releasing portions is between, and inclusive of 0 and 5 percent. As used herein, “porosity” refers to percentage of an area defined by the exterior surface 106 that includes an opening 114 and/or a porous material. In some examples, a porosity of a fluid release portion 112 is configured based in part on a permeability of the fluid and/or on a size of the port 116. In some examples, the openings 114 have a maximum width w1. In some examples, a ratio of the maximum width w1 to a thickness 127 of the corresponding disc 115 is between, and inclusive of, 0.0002 and 0.2. In some examples, the maximum width w1 is between, and inclusive of, 0.5 and 100 micrometers (μm).

As shown in FIG. 3B, in some examples, while the grooves 108 extend around less than an entire circumference of the elongated member 104, the fluid releasing portions 112 extend about the entire circumference. This helps to enable uniform fluid distribution throughout a surface 155 of the disc 115.

As shown in FIG. 3B, in some examples, the interior channel 110 is substantially parallel to the central axis 126 of the elongated member 104. In some examples, the elongated member 104 is a hollow tube, and the interior channel 110 is a hollow portion of that tube. In some examples, the elongated member 104 includes a proximal end 118 and a distal end 122. Referring to FIGS. 2-4A, in some examples, the elongated member 104 includes a fluid port 116 at the proximal end 118. The interior channel 110 is fluidically open to the fluid port 116 such that fluid is receivable via the fluid port 116 and through the interior channel 110. The interior channel 110 is fluidically closed at the distal end 122. In some examples, the apparatus 102 includes a removable cap configured to fluidically close the distal end 122.

Referring to FIG. 4B, in some examples, fluid release portions 112a, 112b, which are closer to the proximal end 118 of the elongated member 104 than to a distal end 122 of the elongated member, are less porous than the fluid release portions 112c, 112d, which are closer to the distal end 122. For example, as shown in FIG. 4B, a quantity of openings 114 in the fluid release portions 112a, 112b is less than a quantity of openings 114 in the fluid release portions 112c, 112d. This arrangement can help to distribute fluid more evenly amongst the discs 115. As the fluid moves along the interior channel 110, portions of the fluid exit the elongated member 104 via the openings 114, leaving less fluid in the interior channel 110 once the fluid reaches the fluid release portions 112c, 112d closer to the distal end 122. As such, the greater quantity of openings 114 in the fluid release portions 112c, 112d closer to the distal end 122 creates greater porosity in the fluid release portions 112c, 112d closer to the distal end 122 and facilitates substantially uniform distribution of fluid amongst the discs 115. As used herein, “more porous” includes portions with a greater porosity than other portions.

Referring to FIG. 4C, in some examples, the central axis 124 of the disc 115 is offset from the central axis 126 of the elongated member 104 when the disk 115 is supported on the elongated member 104. As such, in some examples, although the fluid releasing portions 112 extend around an entirety of the circumference of the elongated member 104, certain portions 140 of the perimeter of the opening 128 are closer to the fluid release portions 112 than other portions of the opening 128. In some examples, portions of each fluid release portion 112 that are closer to the grooves 108 are less porous than portions of the same fluid release portion 112 that are further away from the grooves 108 along the circumference of the elongated member 104. This can help to distribute fluid more evenly along a surface of a disc 115.

In some examples, the elongated member 104 is a monolithically-constructed mandrel that includes both the fluid-releasing portions 112 and the grooves 108 of the exterior surface 106. In some examples, the fluid release portions 112 are made of the same material as the grooves 108. In some examples, the material is a material that would not be porous without the openings 114, such as a metal alloy. In some examples, that material is stainless steel. In some examples, the fluid release portions 112 include perforated stainless steel. In some examples, the fluid release portions 112 are made of a metallic mesh. In other examples, the fluid release portions 112 are made of a different material than the grooves 108 that is more porous than the material of the grooves 108.

In some examples, the fluid port 116 includes an opening that is fluidically connected to the interior channel 110. Referring to FIG. 2, in some examples, the system 100 includes a fluid source 134. The fluid source 134 is fluidically open to the fluid port 116. In some examples, the fluid port 116 includes threading and/or another mechanism to facilitate connection to the fluid source. As such, fluid is flowable from the fluid source 134, into the interior channel 110 via the fluid port 116, along a length L of the interior channel 110, and out of the interior channel 110 via the openings 114. In some examples, the system 100 includes a valve configured to control the flow of fluid from the fluid source 134 to the port 116.

In some examples, the fluid source 134 includes a container holding the fluid, such as a tank of fluid. Referring to FIG. 2, in some examples, the fluid source 134 is located exterior to a chamber 136 in which the elongated member 104 is located. In some examples, the fluid source 134 is fluidically connected to the port 116 through a wall of the chamber 136. In other examples, the fluid source 134 is located within the chamber 136.

As shown in FIG. 2, in some examples, the chamber 136 is enclosed and defines an interior cavity 137. In some examples, the elongated member 104 is positioned within the interior cavity 137. In some examples, the chamber 136 is a vacuum chamber. In some examples, the chamber 136 includes a surface 138 (e.g., a surface of a wall of the chamber 136). In some examples, the surface 138 faces the interior cavity 137 of the chamber 136. In some examples, the elongated member 104 is fixedly coupled to the surface 138 at the fluid port 116. In some examples, the elongated member 104 is fixedly coupled to the surface 138 such that the elongated member 104 extends at an angle with respect to the surface 138. In some examples, the elongated member 104 is substantially perpendicular to the surface 138. As used herein, “substantially perpendicular to” includes an angle between and inclusive of 80 to 100 degrees. In some examples, the discs 115, when loaded onto the grooves 108, are substantially parallel to the surface 138. In some examples, the elongated member 104 is fixed to the surface 138 and the grooves 108 are arranged on the elongated member such that gravity helps to enable the portions 140 of the discs 115 to be secure within the grooves 108.

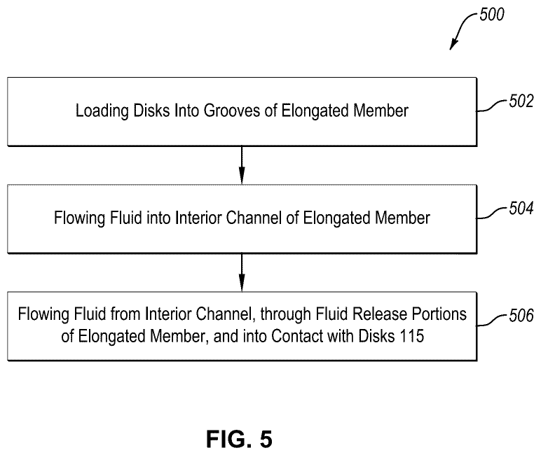

Referring to FIG. 5, a method 500 of distributing fluid onto one or more discs 115, according to one or more examples of the present disclosure, includes (block 502) loading each one of the plurality of discs 115 into a corresponding one of a plurality of grooves 108 formed in an exterior surface 106 of an elongated member 104 so that the plurality of discs 115 are perpendicular relative to a central axis 124 of the elongated member 104. In some examples, the portion of the corresponding one of the discs 115 is only part of an opening 128 of the disc 115 that is less than entire circumference of the opening 128. In some examples, the loading (block 502) includes inserting the elongated member 104 through openings 128 of the discs 115.

In some examples, the method 500 includes flowing (block 504) fluid into the interior channel 110 of the elongated member 104. In some examples, the interior channel 110 is parallel to the central axis 124 of the elongated member 104. In some examples, flowing (block 504) fluid into the interior channel 110 includes flowing the fluid through the interior channel 110 in a longitudinal direction.

In some examples, the method 500 includes flowing (block 506) fluid from the interior channel 110, through fluid release portions 112 of the elongated member 104, and into contact with the plurality of discs 115. In some examples, each one of the fluid release portions 112 is adjacent to a corresponding one of the plurality of grooves 108 or interposed between corresponding adjacent ones of the plurality of grooves 108. In some examples, flowing (block 506) the fluid through the fluid release portions 112 includes flowing the fluid in a radial direction that is perpendicular to the longitudinal direction. In some examples, each fluid release portion 112 includes at least one opening 114, and flowing (block 506) the fluid through the fluid release portions includes flowing the fluid through the at least one opening 114.

In some examples, fluid from at least one of the fluid release portions 112 contacts only one side of one disc 115 of the plurality of discs 115 and fluid from at least one other fluid release portion 112 of the fluid release portions 112 contacts at least one side of at least two discs 115 of the plurality of discs 115. Referring to FIG. 4A, in some examples, fluid from a fluid release portion 112 located closest to the distal end 122 contacts only one side 155 of the disc 115. In some examples, fluid from an adjacent fluid release portion 112 contacts an opposite side 154 of the disc 115 as well as a side of an adjacent disc 115.

In the above description, certain terms may be used such as “up,” “down,” “upper,” “lower,” “horizontal,” “vertical,” “left,” “right,” “over,” “under” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object. Further, the terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise. Further, the term “plurality” can be defined as “at least two.”

As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to” and/or as being “operative to” perform that function.

The term “about” or “substantially” in some embodiments, is defined to mean within +/−5% of a given value, however in additional embodiments any disclosure of “about” may be further narrowed and claimed to mean within +/−4% of a given value, within +/−3% of a given value, within +/−2% of a given value, within +/−1% of a given value, or the exact given value. Further, when at least two values of a variable are disclosed, such disclosure is specifically intended to include the range between the two values regardless of whether they are disclosed with respect to separate embodiments or examples, and specifically intended to include the range of at least the smaller of the two values and/or no more than the larger of the two values. Additionally, when at least three values of a variable are disclosed, such disclosure is specifically intended to include the range between any two of the values regardless of whether they are disclosed with respect to separate embodiments or examples, and specifically intended to include the range of at least the A value and/or no more than the B value, where A may be any of the disclosed values other than the largest disclosed value, and B may be any of the disclosed values other than the smallest disclosed value.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example, without limitation, two of item A, one of item B, and ten of item C; four of item B and seven of item C; or some other suitable combination.

Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

The schematic flow chart diagrams included herein are generally set forth as logical flow chart diagrams. As such, the depicted order and labeled steps are indicative of one example of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

The present subject matter may be embodied in other specific forms without departing from its spirit or essential characteristics. The described examples are to be considered in all respects only as illustrative and not restrictive. All changes which come within the meaning and range of equivalency of the claims are to be embraced within their scope.

1. An apparatus for supporting discs, the apparatus comprising:
an elongated member comprising:
an exterior surface comprising grooves spaced apart from each other along a length of the elongated member, wherein each one of the grooves is configured to receive a portion of a corresponding one of the discs;
an interior channel extending along the length of the elongated member; and
fluid release portions spaced apart from each other along the length of the elongated member and each comprising at least one opening extending from the interior channel to the exterior surface, wherein each one of the grooves is interposed between corresponding adjacent ones of the fluid release portions.

2. The apparatus according to claim 1, wherein each one of the grooves defines a fluid non-releasing portion of the exterior surface.

3. The apparatus according to claim 1, wherein:
the elongated member further comprises a fluid port at a proximal end of the elongated member;
the interior channel is fluidically open to the fluid port;
the interior channel is fluidically closed at a distal end of the elongated member; and
the fluid is flowable into the interior channel, from the fluid port, and out of the interior channel, through the at least one opening of each one of the fluid release portions.

4. The apparatus according to claim 3, wherein the fluid is flowable through the interior channel in a longitudinal direction and through the at least one opening of each one of the fluid release portions is in a radial direction perpendicular to longitudinal direction.

5. The apparatus according to claim 4, wherein:
at least one of the fluid release portions is closer to a proximal end of the elongated member than to a distal end of the elongated member;
at least one of the fluid release portions is closer to the distal end than to the proximal end; and
the at least one of the fluid release portions closer to proximal end is less porous than the at least one of the fluid release portions close to the distal end.

6. The apparatus according to claim 5, wherein:
each one of the at least one of the fluid release portions closer to proximal end comprises a first number of openings;
each one of the at least one of the fluid release portions closer to the distal end comprises a second number of openings; and
the second number is greater than the first number.

7. The apparatus according to claim 1, wherein the elongated member comprises a mandrel and a portion of each one of the discs received by each one of the grooves comprises a portion of a central opening of each one of the discs.

8. The apparatus according to claim 1, wherein each one of the fluid release portions extends about an entire circumference of the elongated member.

9. The apparatus according to claim 8, wherein the grooves extend about less than the entire circumference of the elongated member.

10. The apparatus according to claim 1, wherein the at least one opening of each one of the fluid release portions has a maximum width and a ratio of the maximum width to a thickness of the corresponding disc is between, and inclusive of, 0.0002 and 0.20.

11. The apparatus of claim 1, wherein the fluid release portions have a porosity of between, and inclusive of, 6 percent and 60 percent.

12. The apparatus of claim 1, wherein each groove of the grooves is configured to receive the portion of the corresponding one of the discs such that an elongated-member central axis of the elongated member is parallel to and offset from a disc central axis of the corresponding disc.

13. The apparatus according to claim 1, wherein the grooves and the fluid release portions are made of a metallic material.

14. A system for supporting discs, the system comprising:
an apparatus comprising:
an elongated member comprising:
an exterior surface comprising grooves spaced apart from each other along a length of the elongated member, wherein each one of the grooves is configured to receive a portion of a corresponding one of the discs;
an interior channel extending along the length of the elongated member;
fluid release portions spaced apart from each other along the length of the elongated member and each comprising at least one opening extending from the interior channel to the exterior surface, wherein each one of the grooves is interposed between corresponding adjacent ones of the fluid release portions; and
a fluid port at a proximal end of the elongated member,
wherein the interior channel is fluidically open to the fluid port; and
a fluid source fluidically open to the fluid port.

15. The system according to claim 14, further comprising an enclosed chamber defining an interior cavity, wherein the elongated member is within the interior cavity and fixedly coupled to a surface of the enclosed chamber at the fluid port, and wherein the elongated member extends substantially perpendicular to the surface.

16. A method comprising:
loading each one of a plurality of discs into a corresponding one of a plurality of grooves formed in an exterior surface of an elongated member so that the plurality of discs are perpendicular relative to a central axis of the elongated member;
flowing fluid into an interior channel of the elongated member that is parallel to the central axis; and
flowing the fluid from the interior channel, through fluid release portions of the elongated member, and into contact with the plurality of discs, wherein each one of the fluid release portions is adjacent a corresponding one of the plurality of grooves or interposed between corresponding adjacent ones of the plurality of grooves.

17. The method according to claim 16, wherein fluid from at least one of the fluid release portions contacts only one side of one disc of the plurality of discs and fluid from at least one other fluid release portion of the fluid release portions contacts at least one side of at least two discs of the plurality of discs.

18. The method according to claim 17, wherein:
flowing the fluid into the interior channel comprises flowing the fluid through the interior channel in a longitudinal direction; and
flowing the fluid through the fluid release portions comprises flowing the fluid in a radial direction that is perpendicular to the longitudinal direction.

19. The method according to claim 16, wherein each fluid release portion comprises at least one opening and flowing the fluid through the fluid release portions comprises flowing the fluid through the at least one opening.

20. The method according to claim 16, wherein the portion of the corresponding one of the discs comprises only part of an opening of the disc that is less than an entire circumference of the opening and loading each one of the plurality of discs into a corresponding one of the grooves of the elongated member comprises inserting the elongated member through the opening.
